(19) United States
(12) Patent Application Publication
(10) Pub. No.: US 2025/0052822 A1
(43) Pub. Date: Feb. 13, 2025

(54) A Battery Thermal Testing System and Apparatus

(71) Applicant: Cognition Energy Ltd, Oxfordshire (GB)

(72) Inventors: Tom Cleaver, Oxfordshire (GB); Charles Bertram Boakes, Oxfordshire (GB); Oisin Shaw, Oxfordshire (GB); Campbell Pollock, Oxfordshire (GB); Michael Wilkinson, Oxfordshire (GB); Neal Kanabar, Oxfordshire (GB); Max Naylor Marlow, Oxfordshire (GB); Anthony Robert Hawkes, Oxfordshire (GB); Waseem Marzook, Oxfordshire (GB); Yatish Patel, Oxfordshire (GB)

(21) Appl. No.: 18/719,663

(22) PCT Filed: Dec. 15, 2022
(86) PCT No.: PCT/GB2022/053245

§ 371 Date: Jun. 13, 2024

(30) Foreign Application Priority Data
Dec. 17, 2021 (GB) 2118432.0

(51) Int. Cl. G01R 31/374; H01M 10/42; H01M 10/48

(52) U.S. Cl. CPC G01R 31/374; H01M 10/4285; H01M 10/486

(57) ABSTRACT

An electrochemical cell thermal testing fixture and related apparatus are provided for connection to a battery cycler. The thermal testing fixture comprises a temperature-controlled plate configured to contact a surface of a cylindrical electrochemical cell, and a cell stand, comprising positive and negative contacts, configured to receive the cell. In some examples, the negative contact is configured to contact the sidewall of a cylindrical cell. An electrochemical cell thermal testing fixture system is also provided, comprising a plurality of individually controlled thermal testing fixtures coupled together.

### FIELD OF THE INVENTION

The present disclosure relates to the field of battery testing, in particular electrochemical cell thermal testing fixtures and systems, electrochemical cell electrical connection apparatus, and an electrochemical cell temperature testing device.

### BACKGROUND

The field of battery technology is a rapidly expanding. Consequently, battery testing is also becoming increasingly important for testing battery pack designs and battery performance.

Traditional laboratory methods for testing batteries include the use of thermal chambers or temperature-controlled immersive baths. Both thermal chambers and immersive baths control the temperature of fluid surrounding an electrochemical cell to provide convective cooling or heating. However, convective cooling is not representative of how most cells are used in battery packs in which thermal management systems generally aim to control a specific surface temperature of the cells by conduction. Therefore, the data resulting from convective cooling tests may not accurately represent the cells behaviour in battery packs.

Thermal chambers and immersive baths are also subject to further limitations. For example, all tests in a chamber or bath must be running at the same temperature, preventing variation in control across different cells. This often leads to test regimes taking longer and/or requiring more costly equipment. Similarly, as all cells are in the same chamber or bath, all tests must conclude before the test is able to be changed, leading to significant downtime in battery cycler lines.

The reliability of data obtained from these methods is also compromised by the quality of the electrical connection between the cell and the battery cycler. The quality of connection must be reproducible such that comparisons can be made across different tests. This is often not the case with traditional connection methods, such as the use of crocodile clips or permanent bonding methods, such as spot-welding. Large metal parts are also used in testing for cell level connections due to the low resistance properties, however large metal features also provide thermal pathways for removing heat from cells, reducing the accuracy of thermal test results.

In addition to cell electrical connections, connections between cells and additional sensors, such as strain gauges or temperature sensors, also provides a source of inaccuracy. Traditionally, the sensors are adhered to the cell in the desired location by epoxy or tape which can introduce sources of error, for example due to the unreliable adherence of the sensor and/or imprecise sensor location. The drying time of epoxy can also be disruptive in large test campaigns.

### SUMMARY OF THE INVENTION

Aspects of the invention are as set out in the independent claims and optional features are set out in the dependent claims. Aspects of the invention may be provided in conjunction with each other and features of one aspect may be applied to other aspects.

In a first aspect, there is provided an electrochemical cell thermal testing fixture for connection to a battery cycler, wherein the cell thermal testing fixture comprises a temperature-controlled plate configured to contact at least a surface of a cylindrical battery cell and a cell stand configured to receive the cylindrical cell.

An individual cell testing fixture may be advantageous to reduce the risk of thermal runaway in any neighbouring cells, preventing mass failure events which can be a problem faced by shared testing environments, such as thermal chamber and bath-based testing methods. Individual cell testing fixtures may also reduce downtime in battery cycler lines as cells can be individually controlled, tested, and replaced without affecting other testing lines.

The temperature-controlled plate is configured to heat and/or cool the cell by conduction. Conduction surface heating and cooling of cells may be advantageous compared to convective cooling or heating during cell testing, as conduction surface heating better models cell behaviour in battery packs, wherein most battery pack thermal management systems generally control surface temperature of the cells by conduction.

In some examples, the temperature-controlled plate is configured to contact at least a portion of a circular plane surface of the cylindrical cell. Using a circular planar face of the cell as the thermal contact for heating/cooling by conduction may be advantageous to facilitate homogenous heat transfer through the co-axial layered internal electrode structure within the battery cell. It may also be advantageous as this more accurately models cell performance in battery packs which are commonly base cooled. However, in some examples, the temperature-controlled plate is configured to contact at least a portion of the sidewall surface of the cylindrical cell, instead of contacting at least a portion of a circular plane surface of the cylindrical cell. In other examples, the temperature-controlled plate is configured to contact at least a portion of the sidewall surface of the cylindrical cell, in addition to contacting at least a portion of a circular plane surface of the cylindrical cell, for example wherein the temperature-controlled plate further comprises a receiving portion configured to receive and contact at least a portion of the sidewall surface of the cylindrical cell.

The cell stand comprises a positive contact, configured to contact a positive terminal of the cell, and a negative contact, configured to contact a negative terminal of the cell. The negative contact may be configured to contact a sidewall of the cylindrical cell. In some examples, the negative contact may be biased to engage with the sidewall surface of the cylindrical cell. Contacting the sidewall surface of the cell may be advantageous as this enables the circular planar negative terminal of the cell to be in thermal contact with the temperature-controlled plate. Using a circular planar face of the cell as the thermal contact for heating/cooling by conduction may be advantageous to facilitate homogenous heat transfer through the co-axial layered internal electrode structure within the battery cell.

The electrochemical cell thermal testing fixture may further comprise means configured to bias the cell to contact the temperature-controlled plate. A mechanical biasing means may be advantageous to ensure good thermal contact between the cell and the plate, facilitating good thermal conduction. In some examples, the biasing means configured to bias the cell to contact the temperature-controlled plate may comprise the positive contact such that the biasing means is further configured to bias the positive contact to contact the cell. The biasing means may be advantageous to ensure good electrical contact between the cell and the positive contact.

In some examples, the positive contact may comprise a pin and crown, for example a coaxial pin and/or a serrated crown. The pin may be configured to provide the voltage sense for connection to a battery cycler and crown may be configured to provide a current carrying pathway for connection to a battery cycler. However, the skilled person will understand other positive contact configurations can be used.

The temperature-controlled plate may comprise at least one heating and/or cooling element configured to control the temperature of the plate. In some examples, the at least one heating and/or cooling element may comprise at least one thermoelectric module, for example a Peltier element.

The temperature-controlled plate may further comprise at least one temperature sensor configured to sense the temperature of the temperature-controlled plate. The temperature-controlled plate may also comprise a local processor, wherein the processor is configured to adjust the temperature of the temperature-controlled plate in response to an indication of the temperature sensed by the temperature sensor. In some examples, the processor may adjust the temperature of the temperature-controlled plate by adjusting the power supplied to a thermoelectric heating and/or cooling element configured to control the temperature of the plate, for example a Peltier element. In some examples, the local processor may be configured to receive a command signal from a master processor, for example wherein the command signal may comprise a desired temperature setpoint. In response to the command signal, the local processor may be configured to adjust the temperature of the temperature-controlled plate, for example by adjusting the power supplied to a thermoelectric element. In some examples, the master processor may be configured to receive user input, wherein the user inputs the desired temperature setpoint which results in the command signal.

In some examples, the temperature-controlled plate comprises a PCB comprising the at least one temperature sensor configured to sense the temperature of the plate. In some examples, the plate temperature sensor is mechanically biased to contact the plate. For example, the plate temperature sensor may be mechanically biased to contact the plate by, but not limited to, a resilient cut-out portion of the PCB. A mechanical biasing means may be advantageous to ensure good thermal contact between the temperature sensor and the plate, facilitating accurate temperature measurement of the plate.

The electrochemical cell thermal testing fixture may additionally or alternatively comprise at least one temperature sensor configured to sense the temperature of the cell. A temperature sensor configured to sense the temperature of the cell may be advantageous for accurate thermal testing of the cell. In some examples, the temperature sensor configured to sense the temperature of the cell comprises the cell temperature testing device described in more detail in the fourth aspect of the invention.

The electrochemical cell thermal testing fixture may also further comprise a housing, wherein the housing is configured to enclose the cell stand and at least a portion of the temperature-controlled plate. The housing may be made of an insulating material, such as a polymer. The housing may, optionally, comprise a metal liner. The housing may be advantageous to insulate the cell stand and cell, preventing free movement of air and thus reducing heat loss by convection. The housing may also be advantageous to contain ejected gases, materials, and/or flames in the event of cell failure, increasing safety for lab technicians and operators. Individual containment may also reduce the risk of thermal runaway from propagating in any neighbouring cells, preventing a mass failure event, this may be advantageous over shared thermal chamber and bath-based testing methods.

In a second aspect, there is provided an electrochemical cell electrical connection apparatus, comprising a positive contact configured to contact a positive terminal of a cylindrical cell for connection to a battery cycler, and a negative contact configured to contact a negative sidewall surface of the cylindrical cell, for connection to a battery cycler Contacting the sidewall surface of the cell may be advantageous as this frees up the circular planar negative terminal of the cell to be in thermal contact for base cooling without compromising the electrical connection. Using a circular planar face of the cell as the thermal contact for heating/cooling by conduction may be advantageous to facilitate homogenous heat transfer through the co-axial layered internal electrode structure within the battery cell.

The negative contact may comprise a jaw assembly. The jaw assembly may comprise at least a first jaw and a second jaw, wherein the first jaw and the second jaw are configured to contact opposite sides of the cell sidewall surface. The first jaw may be configured to provide a current carrying path and the second jaw may be configured to provide the voltage sense for connection to a battery cycler.

In some examples, the negative contact jaw assembly comprises a third jaw. The third jaw may be vertically aligned with the first jaw, wherein the jaws are arranged such that the second jaw is vertically displaced in between the first jaw and third jaw. The third jaw may be configured to provide a current carrying path for connection to a battery cycler together with the first jaw. The provision of a third jaw may be advantageous to reduce cell torsion and twisting when the first and second jaws are vertically offset. In embodiments wherein the jaw assembly comprises only a first and a second jaw, the first and second jaw are preferably aligned to contact the cell sidewall at the same vertical displacement.

In some examples, the jaws may be serrated or grooved. This may be advantageous to reduce contact resistance.

The jaw assembly may be configured for a first configuration wherein the jaws are configured to contact the sidewall surface of the cylindrical cell, and a second configuration wherein the jaws are displaced such that the cell may be inserted between the jaws. In some examples, the negative contact comprises a closing mechanism configured to reversibly operate the jaw assembly between the first and second configuration. The closing mechanism may optionally comprise at least one spring configured to mechanically bias the jaws to engage with the sidewall surface of the cylindrical cell. A spring, or other mechanical biasing means, may be advantageous to ensure good electrical contact between the jaws and the sidewall of the cell.

The jaw assembly may have advantages when it comes to service, repair, and recycling of the battery cells as it forms a reversible electrical connection to the cell. The jaw assembly may also be advantageous by providing a reproducible electrical connection compared to traditional connection methods, such as the use of crocodile clips or permanent bonding methods, such as spot-welding. A reproducible electrical connection may be advantageous, for example, to facilitate reliable comparisons across different tests. Another advantage of the jaw assembly may be that the connection does not need expensive machines and therefore can be handled by every lab or workshop.

In some examples, the cell stand of the first aspect of the invention comprises the electrochemical cell electrical connection apparatus of the second aspect of invention. For example, where the positive contact of the first aspect corresponds to the positive contact of the second aspect of the invention, and the negative contact of the first aspect corresponds to the jaw assembly of the second aspect of the invention.

In a third aspect, there is provided an electrochemical cell electrical connection socket for testing cylindrical battery cells, comprising a housing configured to reversibly attach to a positive circular plane surface of a cylindrical cell and at least a portion of the sidewall of the cylindrical cell. The housing further comprises a positive contact configured to contact the positive circular plane surface of a cylindrical cell and a negative contact configured to contact at least one of (i) the sidewall surface of the cylindrical cell, and (ii) a shoulder portion of the cylindrical cell. The shoulder portion of a cylindrical cell may be defined as a circumference portion of the negative terminal enclosing the positive terminal circular plane surface of the cylindrical cell. The positive and negative contacts may be suitable for connection to a battery cycler.

The detachable connection socket may have advantages when it comes to service, repair, and recycling of the battery cells. The socket may also be advantageous by providing a reproducible electrical connection compared to traditional connection methods, such as the use of crocodile clips or permanent bonding methods, such as spot-welding. A reproducible electrical connection may be advantageous, for example, to facilitate reliable comparisons across different tests. Another advantage of the socket may be that the connection does not need expensive machines and therefore can be handled by every lab or workshop.

The housing may be made of an insulating material, for example, but not limited to, a polymer.

In some examples, the negative contact may be configured to at least partially circumferentially enclose at least a portion of the sidewall of the cylindrical cell. In some examples, the negative contact comprises a spring, wherein the length of the spring is configured to enclose the circumference of the cylindrical cell. The negative contact may provide the current carrying connection for connection to a battery cycler. The negative contact further comprises a second contact, for example a second spring configured to enclose the circumference of the cylindrical cell, or a pin configured to contact the negative terminal of the cell, wherein the second contact is configured to provide the negative voltage sense for connection to a battery cycler.

In some examples, the positive contact may comprise a serrated crown configuration and/or a coaxial pin. In some examples, the coaxial pin is configured to provide the voltage sense for connection to a battery cycler. In some examples, the serrated crown is configured to provide a current carrying pathway for connection to a battery cycler. However, the skilled person will understand that, additionally or alternatively, the serrated crown may be configured to provide a voltage sense, and/or the coaxial pin may be configured to provide a current carrying pathway for connection to a battery cycler.

In some examples, the cell stand of the first aspect of invention comprises the electrochemical cell electrical connection socket of the third aspect of the invention. For example, the positive contact of the first aspect may correspond to the positive contact of the third aspect of the invention, and the negative contact of the first aspect may correspond to the negative contact of the third aspect of the invention.

In a fourth aspect, there is provided an electrochemical cell temperature testing device for testing cylindrical battery cells, comprising a clip configured to reversibly attach to at least a portion of a cylindrical cell and at least two temperature sensors arranged along the length of the clip, wherein the clip is configured to mechanically bias the temperature sensors to contact the cell. This may be advantageous as conventionally temperature sensors are adhered to the cell by epoxy or tape which can introduce inaccuracy into measurements, for example due to the imprecise location and/or adherence of the sensor. The drying time of epoxy can also be disruptive in large test campaigns which may be advantageously avoided using this electrochemical cell temperature testing device. In some examples, the temperature sensors are configured to be distributed along the length of the clip, wherein the sensors spaced apart at selected intervals. Optionally, the temperature sensors may be spaced apart at equal intervals.

In some examples, the temperature sensors may be arranged such that, when the clip is attached to a cylindrical cell, the temperature sensors are configured to be arranged along the length of the sidewall of the cylindrical cell. In some examples, the temperature sensors are configured to be distributed along the length of the sidewall of the cylindrical cell, wherein the sensors are spaced apart at selected intervals. Optionally, the temperature sensors may be spaced apart at equal intervals. The clip may be configured to mechanically bias the temperature sensors to contact the sidewall of the cell. In some examples, the device may be configured to measure the temperature gradient along the length of the sidewall of the cylindrical cell, based on the temperature provided by each temperature sensor.

In some examples, the clip is configured to attach to the cylindrical cell by a snap-fit.

In some examples, the electrochemical cell temperature testing device comprises five temperature sensors, however the skilled person will understand that different numbers of temperature sensors may be used. In some examples, the temperature sensors comprise thermistors.

The temperature sensors may be provided on a PCB. The PCB may be sized to fit within the clip. In some examples, the PCB may be a flexible PCB. Where the PCB is flexible, the clip may further comprise a buckle, wherein the buckle is configured to receive the flexible PCB, such that the flexible PCB attaches to the clip.

In some examples, the cell temperature testing device may be configured to communicate the sensed temperature data via a wired connection to a processor. In some examples, the device may be configured to wirelessly communicate the sensed temperature data to a remote device.

In a fifth aspect, there is provided an electrochemical cell thermal testing fixture system comprising a cell temperature testing device of the fourth aspect configured to attach to a cylindrical cell, and a cell testing fixture of the first aspect configured to receive the cell temperature testing device and a cell.

In some examples, the cell stand of the cell testing fixture comprises the electrochemical cell electrical connection apparatus of the second aspect or the electrochemical cell electrical connection socket of the third aspect of the invention.

In a sixth aspect, there is provided an electrochemical cell thermal testing fixture for connection to a battery cycler for testing pouch battery cells, comprising a positive contact, configured to contact a positive terminal of a pouch cell, for example a positive tab, and a negative contact, configured to contact a negative terminal of the pouch cell, for example a negative tab. The electrochemical cell thermal testing fixture also comprises a temperature-controlled plate configured to contact at least a surface of a pouch battery cell, wherein the temperature-controlled plate is configured to heat and/or cool the cell by conduction. In some examples, the temperature-controlled plate may be configured to contact at least one of the tabs of the pouch cell. This may be advantageous as pouch cell tabs may promote good thermal conduction through the pouch cell, due to the good thermal conduction properties of the pouch cell tabs which can facilitate their use as thermal contacts. The electrochemical cell thermal testing fixture may further comprise a cell stand, wherein the cell stand may be configured to receive the pouch cell. The cell stand may comprise the positive and negative contacts. In some examples, the cell stand may further comprise a mechanical biasing means, configured to mechanically bias the at least one pouch cell tab to contact the temperature-controlled plate. This may be advantageous to facilitate a good thermal contact.

In some examples, the electrochemical cell thermal testing fixture of the sixth aspect is the electrochemical cell thermal testing fixture of the first aspect of the invention, wherein the cell stand of the first aspect has been adapted or interchanged such that the cell stand is configured to receive a pouch cell. For example, where the cell stand is interchangeable, the cell stand may be configured to be reversibly attached to the temperature-controlled plate, for example using screws, bolts, a snap fit, or other reversible fixation means.

In a seventh aspect, there is provided a battery thermal testing system comprising a plurality of electrochemical cell testing fixtures, where each electrochemical cell testing fixture is configured to receive a cell. Each cell testing fixture comprises a temperature-controlled plate configured to contact at least one surface of the cell, wherein the temperature-controlled plate is configured to heat and/or cool the cell by conduction. The battery thermal testing system may further comprise a coolant system, wherein the coolant system is configured to cool each of the plurality of electrochemical cell testing fixtures by cooling each temperature-controlled plate. In some examples, the coolant system comprises a fluid cooling system.

In some examples, the plurality of temperature-controlled plates are coupled together, wherein the coupling is a poor thermal conductor and/or thermally insulating. This may be advantageous to thermally decouple the plurality of temperature-controlled plates such that the temperature of each temperature-controlled plate may be independently adjusted and maintained.

Each temperature-controlled plate may comprise at least one heating and/or cooling element configured to control the temperature of the plate. In some examples, the at least one heating and/or cooling element may comprise at least one thermoelectric module, for example a Peltier element. Each temperature-controlled plate may further comprise at least one temperature sensor configured to sense the temperature of the temperature-controlled plate. Each electrochemical cell testing fixture may also comprise a local processor, wherein the processor is configured to adjust the temperature of the corresponding temperature-controlled plate in response to an indication of the temperature sensed by the temperature sensor. In some examples, the processor may adjust the temperature of the temperature-controlled plate by adjusting the power supplied to a thermoelectric heating and/or cooling element configured to control the temperature of the plate, for example a Peltier element.

In some examples, each of the plurality of electrochemical cell testing fixtures is a cell testing fixture of the first, fifth, or the sixth aspects of the invention. In some examples, the plurality of electrochemical cell testing fixtures may comprise a combination of cell testing fixtures of the first aspect of the invention, the sixth aspect of the invention, and/or the fifth aspect of the invention.

In some examples, the cell stand of each electrochemical cell testing fixture may be removable and/or interchangeable. For example, a cell testing fixture of the first aspect of the invention may be adapted into the cell testing fixture sixth aspect of the invention by substituting the cell stand of the first aspect of the invention configured to receive a cylindrical cell, to the cell stand of the sixth aspect of the invention configured to receive a pouch cell. In such examples, the cell stand of each electrochemical cell testing fixture may be reversibly attached to the corresponding temperature-controlled plate, for example by a screw thread, bolts, a snap fit, or other reversible fixation means.

In some examples, the battery thermal testing fixture system may additionally further comprise at least one of (i) a power supply configured to power each of the plurality of cell testing fixtures; and (ii) a battery cycler configured to cycle the cells of each cell testing fixture. In some examples, the battery thermal testing system may further comprise a central processor and a display, wherein the display may be configured to display test parameters and data received from each electrochemical cell testing fixture relating to corresponding electrochemical cell tests. The display may additionally comprise a graphical user interface (GUI). The GUI may be configured to receive user input to control the test parameters for each electrochemical cell testing fixture, for example the GUI may be configured to receive a desired temperature input for each electrochemical cell testing fixture. The central processor may be configured to communicate individual temperature inputs to the corresponding electrochemical cell testing fixtures. In some examples, each electrochemical cell testing fixture may be configured to control its temperature locally and independently in response to a received temperature input.

### DRAWINGS

Embodiments of the disclosure will now be described, by way of example only, with reference to the accompanying drawings, in which:

FIGS. 1A and 1B show example battery thermal testing systems comprising a series of electrochemical cell thermal testing fixtures.

FIG. 2 shows a schematic of a cylindrical electrochemical cell.

FIGS. 3A and 3B show an example cell stand comprising a jaw assembly, for example for use in the example battery thermal testing system shown in FIGS. 1A and 1B. FIG. 3C shows an example electrochemical cell thermal testing fixture, including the example cell stand of FIGS. 3A and 3B and a temperature-controlled plate, for example for use in the example battery thermal testing system shown in FIGS. 1A and 1B.

FIG. 4 shows an example jaw assembly for use as a negative contact, for example for use in the example electrochemical cell thermal testing fixture shown in FIGS. 3A to 3C.

FIG. 5 shows an example positive contact, for example for use in the cell stand shown in FIGS. 3A to 3C.

FIG. 6 shows an example electrochemical cell electrical connection socket, for example for use in an electrochemical cell thermal testing fixture.

FIG. 7A shows an example electrochemical cell temperature testing device for use with a cylindrical cell. FIG. 7B shows an example clip, for example for use with the electrochemical cell temperature testing device of FIG. 7A.

FIG. 8 shows an example electrochemical cell thermal testing fixture system, for example for use in the example battery thermal testing system shown in FIGS. 1A and 1B, comprising the electrochemical cell thermal testing fixture of FIG. 3C and the electrochemical cell temperature testing device of FIG. 7A.

FIG. 9A shows a schematic of a temperature control system associated with a temperature-controlled plate, for example the temperature-controlled plate for use in the example electrochemical cell thermal testing fixture of FIG. 3C, for use in the example battery thermal testing system of FIGS. 1A and 1B.

FIG. 9B shows a cross-section of an example battery thermal testing system comprising a series of electrochemical cell thermal testing fixtures, for example the battery thermal testing system of FIGS. 1A and 1B. The cross-section shows an example temperature control system associated with a temperature-controlled plate, for example as schematically illustrated in FIG. 9A.

FIGS. 10A and 10B show example PCB cut-out designs, comprising a temperature sensor, for use with a temperature-controlled plate, for example the temperature-controlled shown in FIGS. 9A and 9B.

FIG. 11 shows an example schematic of an example battery thermal testing system, for example the example battery thermal testing system of FIGS. 1A and 1B.

### SPECIFIC DESCRIPTION

Embodiments of the claims relate to electrochemical cell thermal testing fixtures and systems. Embodiments of the claims also relate to an electrochemical cell electrical connection apparatus, an electrochemical cell electrical connection socket, and an electrochemical cell temperature testing device.

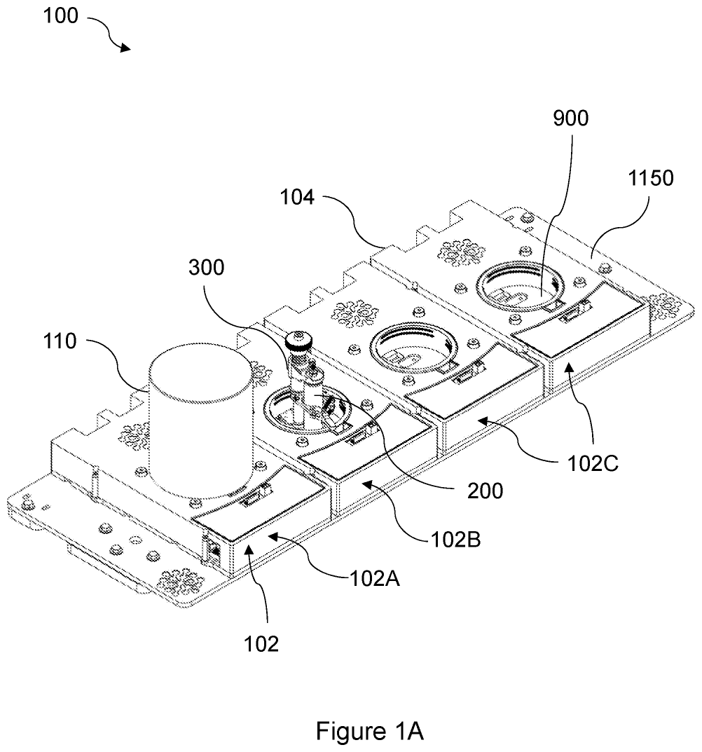

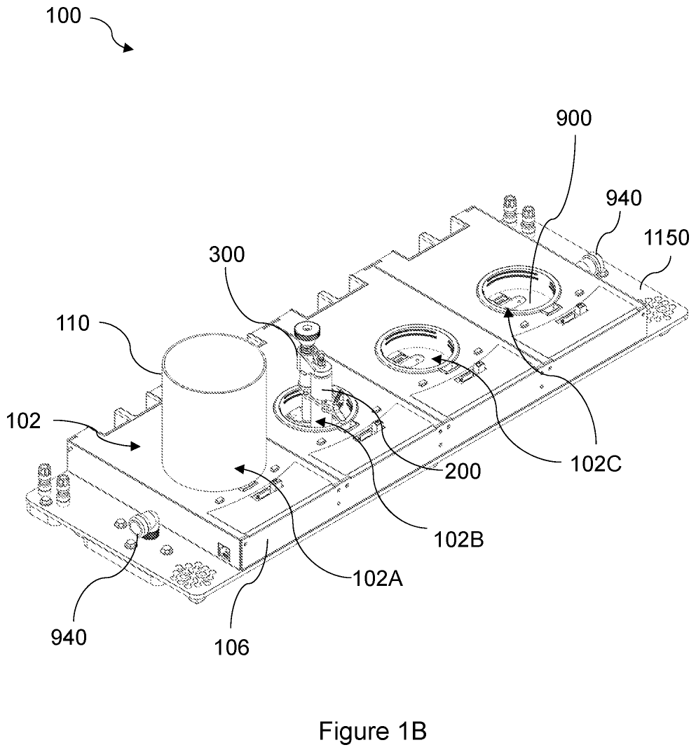

FIGS. 1A and B show an example battery thermal testing system 100 comprising a series of electrochemical cell thermal testing fixtures 102. In these examples, the system 100 comprises four electrochemical cell thermal testing fixtures 102, however the skilled person will understand that any number of thermal testing fixtures 102 may be used. FIG. 1A comprises each of the plurality of thermal testing fixtures 102 in an individual casing 104, whereas FIG. 1B comprises each of the plurality of thermal testing fixtures 102 in a shared casing 106. Electrochemical cell thermal testing fixture 102A comprises a housing 110. The housing 110 may be made of an insulating material, such as a polymer, and, optionally, comprise a metal liner. The housing 110 may be advantageous to insulate to a cell stand 300 and cell 200 enclosed by the housing 110, preventing free movement of air and thus reducing heat loss by convection. The housing 110 may also be advantageous to contain ejected gases, materials, and/or flames in the event of cell failure, increasing safety for lab technicians and operators. Individual containment may also reduce the risk of thermal runaway from propagating in neighbouring cell thermal testing fixtures 102, preventing a mass failure event.

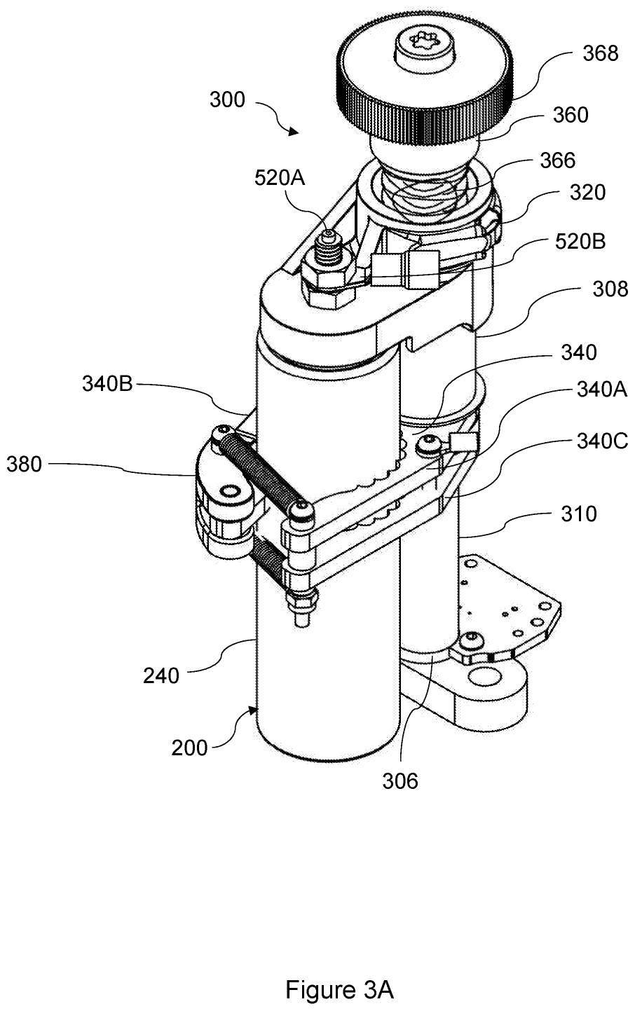

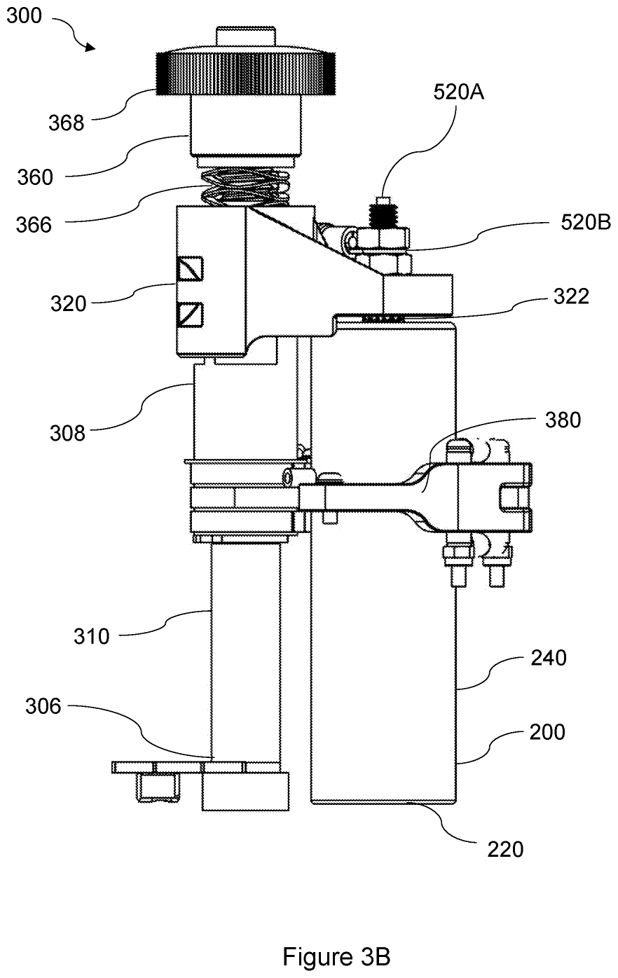

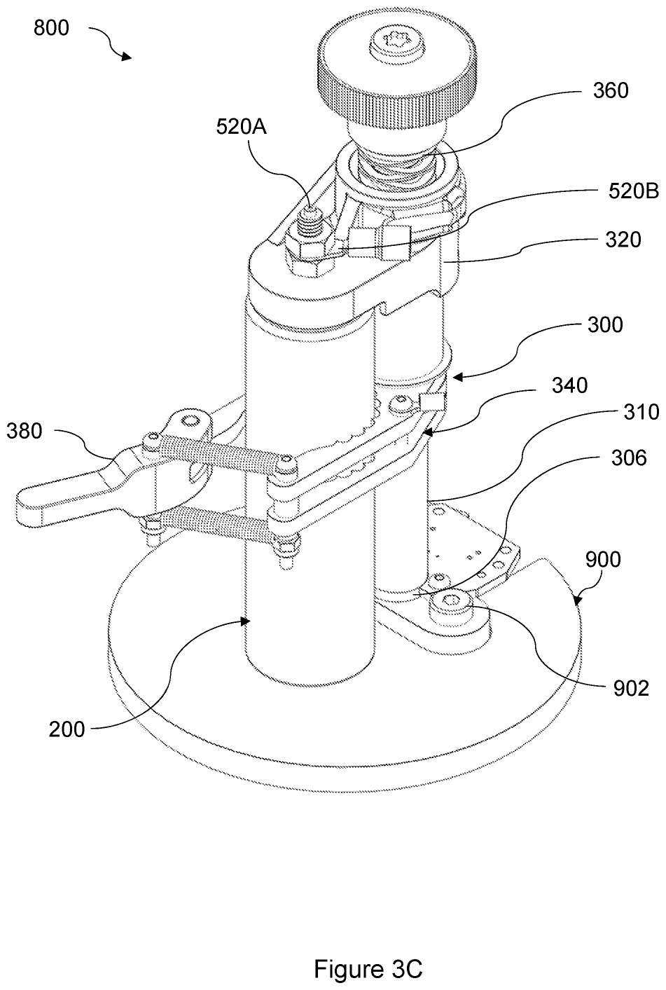

For illustrative purposes, electrochemical cell thermal testing fixture 102B is shown with the housing 110 removed. This shows the arrangement of the cell stand 300 containing a cylindrical cell 200. An example cell stand is shown in more detail in FIGS. 3A to 3C.

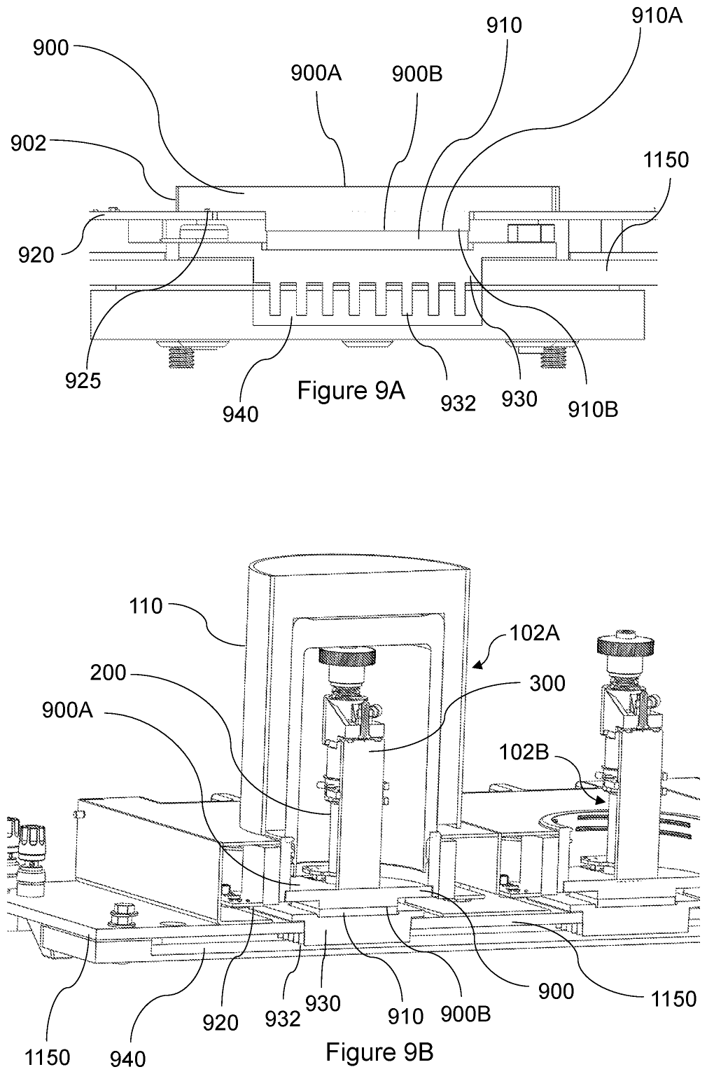

For illustrative purposes, electrochemical cell thermal testing fixtures 102C are shown with the housing 110, cell stand 300, and cylindrical cell 200 removed. This shows a temperature-controlled plate 900 to which a cell stand 300 is attached. An example temperature-controlled plate 900 and its associated temperature control system is shown in more detail in FIGS. 9A and 9B.

Each of the plurality of electrochemical cell testing fixtures 102 are coupled together, wherein the coupling 1150 is a poor thermal conductor and/or thermally insulating. This may be advantageous to thermally decouple the plurality of electrochemical cell testing fixtures 102, in particular thermally decoupling the temperature-controlled plates 900, such that the temperature of each electrochemical cell testing fixture 1102 may be independently adjusted and maintained. In this example, the coupling 1150 is a polymer, however the skilled person will understand other poor thermally conducting materials may be used.

The cell stand 300 is configured to receive a cell. In the example shown, the cell stand 300 is configured to receive a cylindrical cell 200, as shown in more detail in FIGS. 3A to 3C. However, the skilled person will understand that the electrochemical cell fixtures 102 are not limited to receiving cylindrical cells.

As illustrated by cell thermal testing fixtures 102C, the cell stand 300 of each electrochemical cell thermal testing fixture 102 is configured to be removable and/or interchangeable. For example, a cell testing fixture 102 may be adapted to receive different electrochemical cell types by substituting different types of cell stands, for example but not limited to, substituting the cell stand 300 shown in 102B configured to receive a cylindrical cell 200 for a different cell stand configuration, configured to receive a pouch cell. In such examples, the cell stand of each electrochemical cell testing fixture may be reversibly attached to the corresponding temperature-controlled plate 900, for example by a screw thread, bolts, a snap fit, or other reversible fixation means, as seen in more detail in FIG. 3C. The plurality of electrochemical cell testing fixture 102 may comprise the same, different, or a combination of different types of cell stands, configured to receive different cell types.

The temperature-controlled plate 900 is configured to contact a surface of the cell for heat transfer by conduction. Each cell thermal testing fixture 102 can therefore individually control the temperature of its corresponding cell.

In use, the battery thermal testing system 100 may be connected to a battery cycler, wherein the cycler is configured to test cells in each of the plurality of electrochemical cell testing fixtures 102.

By operating multiple cell testing fixtures 102, electrochemical cell performance can be simultaneous tested across a range of different temperatures in a relatively small amount of space. The variety and flexibility achievable for simultaneous tests may be advantageous over traditionally battery testing methods. Tests in each of the plurality of electrochemical cell testing fixtures 102 can also be independently stopped and restarted without affecting the other testing regimes in coupled electrochemical cell testing fixtures 102, reducing battery cycler downtime.

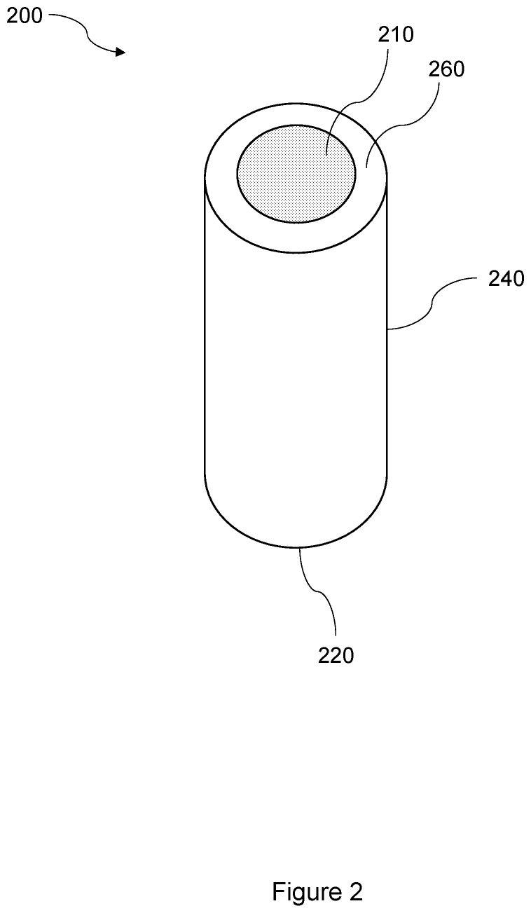

FIG. 2 shows a schematic of a typical cylindrical battery cell 200, shown for illustration purposes. The positive terminal of the cell is provided as a positive circular plane surface 210 of the cylindrical cell. The negative terminal of the cell is provided by the entirety of the curved sidewall 240 of the cylinder and the circular plane surface 220 opposite the positive terminal. The negative terminal of the cell may also include a negative circumference portion 260 enclosing the positive circular plane surface 210 of the cylindrical cell 200, known as the cell shoulder 260.

Traditionally, the cell 200 is covered in a heat shrink wrapping exposing only the circular plane surface 220 of the cell for negative connection and the positive circular plane surface 210 for positive connection. However, the wrapping may be removed to expose the cell 200, including the negative sidewall 240.

FIGS. 3A and 3B show different views of an example cell stand 300, for example for use in a battery thermal testing fixture 102 shown in FIGS. 1A and 1B. In the example shown, the cell stand 300 is shown including a cylindrical cell 200, illustrating the set-up in use.

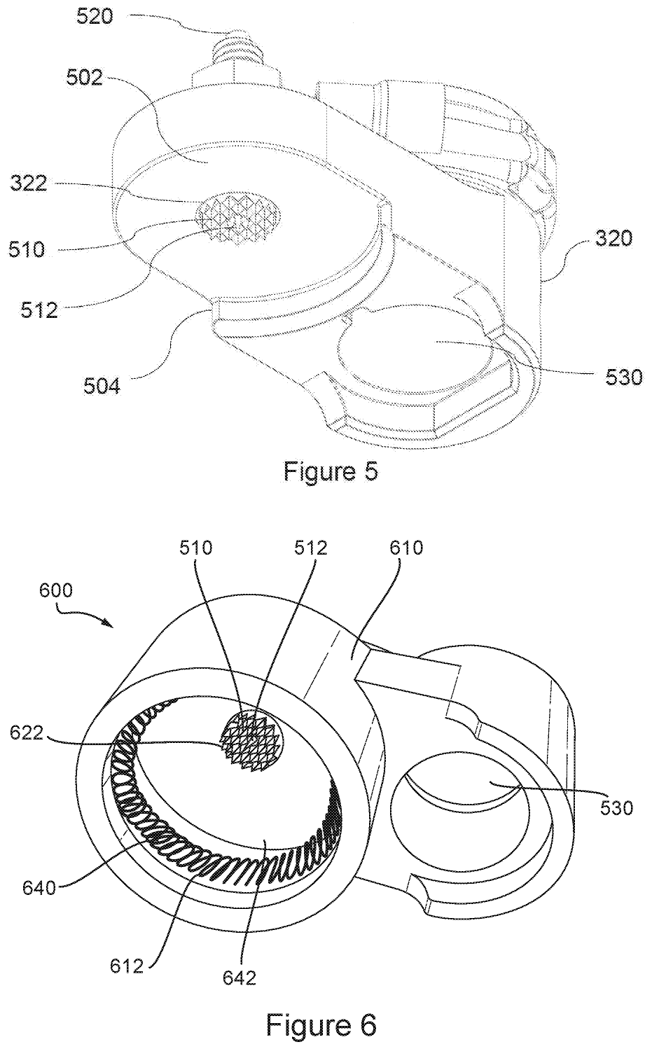

The cell stand 300 comprises a vertical member 310 wherein the distal end 308 of the vertical member 310 receives a cell cap 320. The cell cap 320 comprises a positive contact 322. An example cell cap 320 is shown in more detail in FIG. 5. A mechanical biasing means 360 is coupled to the cell cap 320, in this example the biasing means 360 comprises a knob 368 and a spring 366.

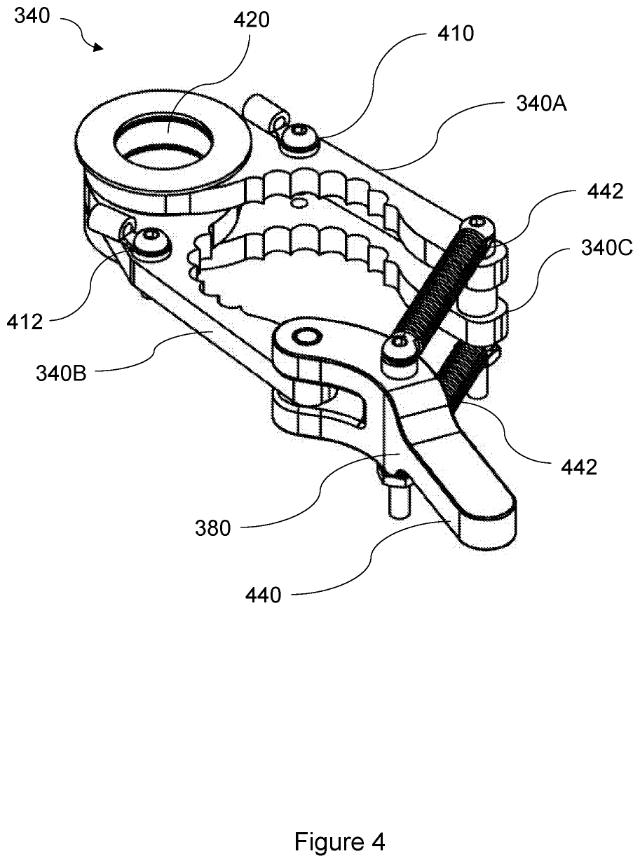

In this example, the vertical member 310 supports a jaw assembly 340. An example jaw assembly 340 is shown in more detail in FIG. 4. In the example shown, the jaw assembly 340 comprises a first jaw 340A, a second jaw 340B, and a third jaw 340C. However, the skilled person will understand that other jaw assembly configurations may be used, such as, but not limited to, a jaw assembly comprising solely of a first jaw and a second jaw, wherein the first jaw and the second jaw are configured to contact opposite sides of the cell sidewall surface.

The jaw assembly 340 further comprises a closing mechanism 380 which links the first jaw 340A and third jaw 340C to the second jaw 340B. The closing mechanism 380 is electrically insulated from the electrical contact provided by the jaws. The closing mechanism is also shown in more detail in FIG. 4.

The positive contact 322 of the cell cap 320 is configured to contact the positive terminal of the cell 200.

The cell cap 320 is configured to support the cell 200 in a vertical configuration via connection to the vertical member 310 of the cell stand 300. The biasing means 360 is configured to apply a mechanical force to the cell cap 320 to contact the positive terminal of the cell 200. This may be advantageous to facilitate a good electrical connection between the positive contact 322 and the cell 200. In this example, the force is configured to be adjusted by turning the knob 365 which is configured to compress or release the spring 366; however the skilled person will understand that other means configured to apply a force to the cell cap 320 to contact the positive terminal of the cell 200 may be used instead, for example a screw press mechanism.

The jaw assembly 340 is configured to contact the sidewall surface 240 of the cylindrical cell 200 to provide a negative contact. The first jaw 340A and third jaw 340C are configured to provide a current carrying path for connection to a battery cycler, and the second jaw 340B is configured to provide the voltage sense for connection to a battery cycler.

The jaw assembly 340 may additionally be configured to support the cylindrical cell 200 in a vertical configuration, parallel to the vertical member 310 of the cell stand 300.

The jaw assembly 340 is additionally configured to transition between a first configuration wherein the jaws 340A, 340B, and 340C are configured to contact the sidewall 240 surface of the cylindrical cell 200 (as shown in FIGS. 3A and 3B), and a second configuration wherein the jaws 340A, 340B, and 340C are displaced such that the cell 200 may be inserted between the jaws 340A, 340B, and 340C (as shown in FIG. 3C).

FIG. 3C shows an example electrochemical cell thermal testing fixture 800 wherein the proximal end 306 of the vertical member 310 of the cell stand 300, shown in FIGS. 3A and 3B, is attached to a temperature-controlled plate 900. An example temperature-controlled plate 900 and its associated temperature control system is shown in more detail in FIGS. 9A and 9B. In this example, the cell stand 300 is secured to the temperature-controlled plate 900 with a bolted connection 902, however the skilled person will understand other reversible connections may be used, including but not limited to using screw, or a snap-fit connection. In the example shown, the cell stand 300 is shown including a cylindrical cell 200, illustrating the set-up in use.

The biasing means 360 is additionally configured to apply a mechanical force to the cell cap 320 such that, in use, the cell cap 320 forces the cell 200 to contact the temperature-controlled plate 900. This may be advantageous to facilitate a good thermal contact for heat conduction between the cell 200 and the temperature-controlled plate 900. As above, the force is configured to be adjusted by turning the knob 365 which is configured to compress of release the spring 366; however the skilled person will understand that other means configured to apply a force to the cell cap 320 to contact the positive terminal of the cell 200 may be used instead, for example a screw press mechanism.

In use, a cell 200 may be received by the cell stand 300 whilst the jaw assembly 340 is in the second configuration. The cell 200 is inserted parallel to the vertical member 310 of the cell stand 300 between the jaw assembly 340, such that the negative circular face of the cell 220 is in contact with the temperature-controlled plate 900.

The jaw assembly 340 is then transitioned into the first configuration and the closing mechanism 380 is secured. This creates the negative contact to the cell.

The cell cap 320, including the positive contact 322, is then fitted to contact the positive terminal of the cell 200. The pressure the cell cap 320 exerts force on the cell 200 is adjusted by turning the knob which compresses the spring of the mechanical biasing means 360, this biases the cell cap 320 into the cell which in turn facilitates a good electrical connection between the positive contact 322 and the positive terminal of the cell 210, and a good thermal connection between the base circular face to the cell 220 and the temperature-controlled plate 900.

The temperature-controlled plate 900 then heats or cools the cell 200 by conduction.

The positive and negative connections of the cell stand 300 may then be connected to a battery cycler by a four-point connection, for testing of the cell 200.

In the context of the present disclosure other examples and variations of the apparatus and methods described herein will be apparent to a person of skill in the art. For example, the embodiments described above relate to testing cylindrical cells, however the skilled person will understand that cells come in different form factors; thus, the skilled person will understand the system and apparatus may be adapted to facilitate testing other types of electrochemical cell, including coin, pouch, and prismatic cells. For example, in some examples, the cell stand 300 may be adaptable and/or interchangeable, such that the cell stand may receive other types of electrochemical cell, including coin, pouch, and prismatic cells. Where the cell stand 300 is interchangeable, the cell stand 300 may be configured to be reversibly and interchangeably attached to the temperature-controlled plate 900, for example to accommodate a range of electrochemical cells within the same cell testing fixture which may be supported by different cell stands. Different cell stands may include different cylindrical cell stands sized to received different cylindrical cells (e.g., 21700 or 18650 cells), for example such as the cell stand shown in FIG. 3A; or different cell stands configured to receive different types of electrochemical cells, for example coin, pouch, or prismatic electrochemical cells. In some examples, the cell stand 300 may be adapted by interchanging different positive and/or negative contacts onto the same vertical member 310 of the cell stand 300.

For example, an example cell stand configured to receive a pouch cell (not shown) may comprise positive and negative contacts configured to contact the positive and negative tabs of a pouch cell. Additionally, an example cell stand may further comprise a mechanical biasing means, configured to mechanically bias at least one of the tabs of the pouch cell to contact the temperature-controlled plate 900 (akin to the cell cap 320 shown in FIGS. 3A to 3C). This may be advantageous as pouch cell tabs may promote good thermal conduction through the pouch cell, due to the good thermal conduction properties of the pouch cell tabs which can facilitate their use as thermal contacts. In some examples, the cell stand 300 may be adapted by interchanging different positive and/or negative contacts onto the same vertical member 310 of the cell stand 300.

FIG. 4 shows the jaw assembly 340 shown in FIGS. 3A to 3C in more detail. The jaw assembly comprises a first jaw 340A, a second jaw 340B, and a third jaw 340C, wherein all jaws are arranged to be parallel. The first jaw 340A and third jaw 340C are arranged opposite to the second jaw 340B and the jaw assembly 340 is arranged such that the second jaw 340B is vertically displaced between the first jaw 340A and the third jaw 340C. The arrangement of the second jaw 340B in between the two opposite jaws 340A and 340B may be advantageous to reduce torsion of the cell 200 in use with a three-jaw assembly 340. Each jaw is serrated to reduce contact resistance.

The jaw assembly 340 provides the negative contact for electrical connection of a cell to a battery cycler. The first jaw 340A and third jaw 340C are configured to provide a negative current carrying connection 410, and the second jaw 340B is configured to provide the negative voltage sense connection 412. These negative connections 410 and 412 may facilitate easy wiring and connection to a battery cycler.

The proximal ends of the first jaw 340A, second jaw 340B, and third jaw 340C are arranged about a common pivot point, wherein the pivot is characterised by an aperture 420 configured to receive the vertical member 310 of the cell stand 300, shown in FIGS. 3A to 3C.

The jaw assembly 340 further comprises a closing mechanism 380 which links first jaw 340A and third jaw 340C to the second jaw 340B. In this example, the closing mechanism comprises a lever 440, wherein the lever is configured to pivot about the distal end of the second jaw 340B. The lever 440 is coupled to the first jaw 340A and the third jaw 340C by a pair of springs 442. The closing mechanism 380 is electrically insulated from the electrical contact provided by the jaws.

The first jaw 340A and third jaw 340C are configured to contact a first side of the cell sidewall 240 surface, whereas the second jaw 340B is arranged to contact the opposite side of the cell sidewall 240 surface.

The jaw assembly 340 is configured to transition between a first configuration wherein the jaws 340A, 340B, and 340C are configured to contact the sidewall 240 surface of the cylindrical cell 200 (for example, as shown in more detail in FIGS. 3A and 3B), and a second configuration (as shown in FIG. 3C) wherein the jaws 340A, 340B, and 340C are displaced such that the cell 200 may be inserted between the jaws 340A, 340B, and 340C.

The closing mechanism 380 is configured to reversibly secure the jaw assembly 340 in the first configuration.

In use, the lever 440 may be pivoted away from the second jaw 340B. This causes the second jaw 340B to be displaced from the first and third jaws 340A, 340C such that the jaw assembly is transitioned into the second configuration. A cylindrical cell may then be inserted between the jaws 340A, 340B, and 340C.

The lever 440 may then be pivoted towards the second jaw 340B. This causes the second jaw 340B and the first and third jaws 340A, 340C to pivot about the vertical member 310 of the cell stand 300 as shown in FIGS. 3A to 3C (characterised by the aperture 420 in FIG. 4), such that the jaw assembly is transitioned into the first configuration. Once the jaws 340A, 340B, and 340C are contacting the sidewall 240 surface of the cylindrical cell 200, the lever 440 may continue to pivot towards the second jaw 340B which causes the springs 442 to extend. The extended springs 442 exert force on the second jaw 340B and the first and third jaws 340A, 340C to mechanically bias the jaws together, ensuring good electrical contact is maintained between the jaws 340A, 340B, 340C and the sidewall 240 surface of the cell 200 whilst the jaw assembly 340 is in the first configuration.

The example shown in FIG. 4 depicts a three-jaw assembly 340, comprising a first jaw 340A, a second jaw 340B, and a third jaw 340C. However, the skilled person will understand that other jaw assembly configurations may be used, such as, but not limited to, a jaw assembly comprising solely of a first jaw 340A and a second jaw 340B, wherein the first jaw and the second jaw are configured to contact opposite sides of the cell sidewall surface. In some two-jaw assembly configurations, the first and second jaws are arranged to contact the sidewall of a cell 200 at the same height. This configuration may be advantageous to reduce cell torsion.

FIG. 5 shows the cell cap 320, as shown in FIGS. 3A to 3C. The cell cap 320 comprises an aperture 530, sized to receive the distal end 308 of the vertical member 310 of the cell stand 300. The cell cap 320 further comprises a substantially circular receiving portion 502 shaped to receive at least a portion of a cylindrical cell 200. The receiving portion 502 comprises a lip 504 around the innermost edge of the receiving portion 502 within the cap 320. The receiving portion 502 further comprises a positive contact 322. In this example, the positive contact 322 comprises a serrated crown configuration 510 and a coaxial pin contact 512. The serrated crown configuration 510 is electrically insulated from the coaxial pin contact 512. The positive contact 322 is electrically coupled to positive connections 520A and 520B on the opposite surface of the cell cap 320 to the receiving portion 502. The positive connections 520A and 520B may facilitate easy wiring and connection to a battery cycler.

The substantially circular receiving portion 502 is configured to receive to at least a portion of a cylindrical cell 200. The lip 504 is configured to contact the shoulder of the cylindrical cell. This may be advantageous to support the cell in a vertical position, whilst also preventing the cell from contacting the vertical member 310 of the cell stand 310.

The positive contact 322 is configured to contact the positive terminal 210 of the cylindrical cell. The coaxial pin contact 512 is sprung such that it is configured to recede into the cell cap 320 when abutting the positive terminal 210 to enable both the coaxial pin contact 512 and serrated crown configuration 510 contact positive cell terminal 210 simultaneously. In this example, the coaxial pin 512 is configured to provide the voltage sense for connection to a battery cycler and the serrated crown 510 is configured to provide a current carrying pathway for connection to a battery cycler. However, the skilled person will understand that other positive contact configurations may be used. The voltage sense connection and the current carrying connection are connected to a battery cycler through the positive connections 520A and 520B, the positive connections 520A and 520B are shown more clearly in FIGS. 3A to 3C.

In use, the distal end 308 of the vertical member 310 of the cell stand 300 is received through the aperture 530, as shown in FIGS. 3A to 3C. A cylindrical cell 200 is then received by the cell stand 300. The cell positive terminal of the cylindrical cell is received by the receiving portion 502 of the cap 320 and the shoulder of the cylindrical cell abuts the lip 504. The positive contact 322 electrically contacts the positive terminal 210 of the cell 200 and the electrically coupled positive connections 520A and 520B are connected to the battery cycler to provide a positive connection for both the voltage sense connection from the coaxial pin 512, and the current carrying connection from the serrated crown 510.

FIG. 6 shows an electrochemical cell electrical connection socket 600. The socket 600 comprises a housing 610, wherein the housing has a circular opening 612 shaped to coaxially receive to at least a portion of a cylindrical cell. The housing 610 further comprises a positive contact 622 configured to contact a positive terminal 210 of a cylindrical cell 200. In this example, the positive contact 622 comprises a serrated crown configuration 510 and a coaxial pin contact 512. The serrated crown configuration 510 acts as a first positive contact and is electrically insulated from the second positive contact, the coaxial pin contact 512. The positive contact 622 is electrically coupled to a positive connection (not shown) on the opposite surface of the housing 610 to the circular opening 612, for example similar to the positive connections 520A and 520B shown in FIG. 5. The positive connections 520A and 520B facilitate easy wiring and connection to a battery cycler.

The housing 610 further comprises a negative contact 640. In this example, the negative contact 640 comprises a first contact of a spring 642, wherein the spring 642 is arranged around the inner circumference of the opening 612 in the housing 610. The spring 642 may be retained in the opening 612 by a retaining groove in the housing 610.

The negative contact further comprises a second contact (not shown in FIG. 6). The second contact may comprise, for example, a second spring configured to enclose the circumference of the cylindrical cell, or a pin configured to contact the negative terminal of the cell, wherein the second contact is configured to provide the negative voltage sense for connection to a battery cycler. The second negative contact is electrically insulated from the first negative contact. The negative contacts 622 are electrically coupled to corresponding negative connections (not shown) on the opposite surface of the housing 610 to the circular opening 612 to facilitate easy wiring and connection to a battery cycler.

The housing 610 further comprises a circular aperture 530, wherein the aperture is coaxially aligned with the circular opening 612. The circular aperture 530 is sized to receive the distal end 308 of the vertical member 310 of the cell stand 300.

The housing 610 may be made of an insulating material, for example, but not limited to, a polymer.

In this example, the coaxial pin 512 is configured to provide the voltage sense for connection to a battery cycler and the serrated crown 510 is configured to provide a current carrying pathway for connection to a battery cycler. However, the skilled person will understand that other positive contact configurations 622 may be used.

The negative contact 640 is configured to contact at least one of (i) the sidewall 240 surface of the cylindrical cell 200, and (ii) a shoulder portion 260 of the cylindrical cell 200. In this example, the spring 642 is configured to circumferentially enclose a portion of the sidewall 240 of a cylindrical cell 200 when a cylindrical cell 200 is received by the opening 612 in the housing 610. In this example, the spring 642 is configured to provide a current carrying pathway for connection to a battery cycler.

The electrochemical cell electrical connection socket 600 may be configured to replace the cell cap 320 and jaw assembly 340, for use in an electrochemical cell thermal testing fixture, such as the fixture shown in FIG. 3C or the system shown in FIGS. 1A and 1B.

The electrical connection socket 600 may be attached to a cell stand 300 by receiving a cell stand vertical member 310 into the aperture 530 in the socket housing 610.

In use, the opening 612 in the housing 610 may reversibly receive at least a portion of a cylindrical cell 200, such that the positive contact 622 contacts the positive terminal 210 of the cell 200 and the negative contact 640 is configured to contact at the sidewall 240 surface of the cylindrical cell 200. Positive and negative connections may then facilitate a four-point electrical connection, comprising both positive and negative voltage sense and current carrying connections, for connection to a battery cycler.

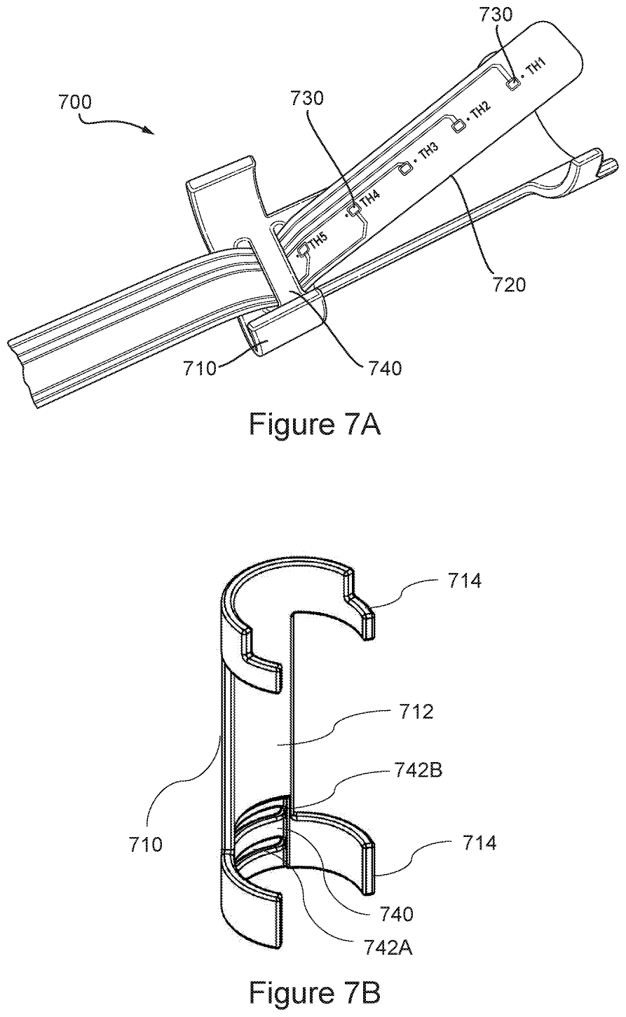

FIG. 7A shows an electrochemical cell temperature testing device 700 for testing cylindrical battery cells. The device 700 comprises a clip 710 which is shown in more detail in FIG. 7B.

The clip 710 comprises an elongate member 712 with a set of arms 714 arranged at each end of the elongate member 712, although it will be understood that in other examples the arms need not be located at an end of the elongate member 712. The elongate member 712 is sized to be substantially the same length as the length of a cylindrical cell being tested. Each set of arms 714 has a semi-annular cross-section, sized to partially enclose the circumference of a cylindrical cell. The clip may be made of a resilient material, for example a resilient polymer.

The electrochemical cell temperature testing device 700 further comprises a plurality of temperature sensors 730 arranged along the length of the clip 710. In the example shown, the electrochemical cell temperature testing device 700 comprises five temperature sensors 730, however the skilled person will understand that different numbers of temperature sensors may be used. In this example, the temperature sensors 730 are equally spaced along the length of the elongate member 712. The temperature sensors may be thermistors.

The temperature sensors 730 are provided on a PCB 720. The PCB 720 is sized to fit within the clip 710. In this example, the PCB 720 is sized to fit within the elongate member 712 of the clip 710. In the example shown, the PCB 720 is flexible.

The clip 710 further comprises a buckle 740. The buckle 740 is located at one end of the elongate member 712, wherein the buckle 740 comprises two parallel, substantially rectangular-shaped apertures, 742A and 742B, sized to receive the flexible PCB 720. The PCB 720 attaches to the clip 710 through the buckle 740, such that the flexible PCB passes through both the first and second apertures 742A and 742B of the buckle 740. However, the skilled person will understand other attachment methods may be possible, including but not limited to adhesive.

The clip 710 is configured to reversibly attach to a cylindrical cell 200. In this example, the clip 710 is configured to attach to the cylindrical cell by an annular snap-fit.

The temperature sensors are arranged such that, when the clip is attached to a cylindrical cell 200, the temperature sensors 730 are configured to be arranged along the length of the sidewall 240 of the cylindrical cell 200. The clip 710 is configured to mechanically bias the temperature sensors 730 to contact the cell.

In use, the device 700 reversibly attaches to a cylindrical cell 200 and measures the temperature of the cell 200 along the cell sidewall 240 using the plurality of temperature sensors 730.

The device 700 may also calculate the temperature gradient along the length of the sidewall 240 of the cylindrical cell 200, based on the temperature provided by each temperature sensor 730 and the relative position of the temperature sensors 730.

In some examples, the device 700 may be configured to communicate the sensed temperature data via a wired connection, for example a wired connection to the PCB 920 of an electrochemical cell thermal testing fixture. In some examples, the device 700 may comprise a wireless communications interface and be configured to wirelessly communicate the sensed temperature data to a remote device.

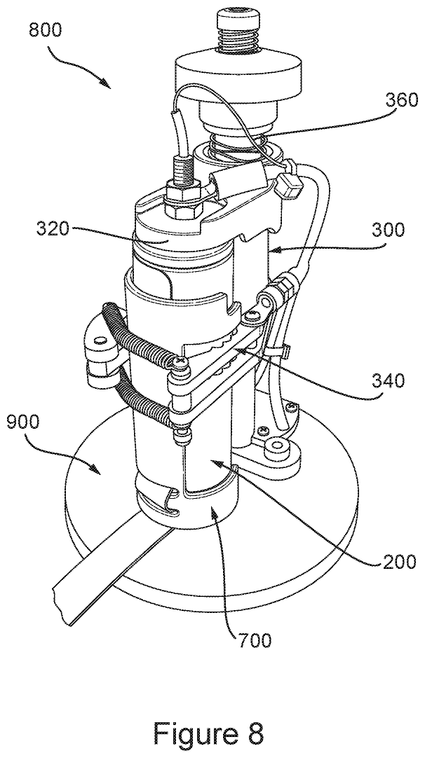

FIG. 8 shows an example electrochemical cell thermal testing fixture system 800 comprising a cell temperature testing device 700, for example as shown in FIGS. 7A, and a cell testing fixture 800, for example as shown in FIG. 3C. The cell testing fixture 800 comprises a cell stand 300 comprising a jaw assembly 340, and a temperature-controlled plate 900. The temperature-controlled plate 900 and its associated temperature-control system is shown in more detail in FIG. 9A. FIG. 8 shows the electrochemical cell thermal testing fixture system 800 in use, comprising an example cylindrical electrochemical cell 200 within the cell stand 300.

In this example, the cell stand 300 comprises the cell cap 320 and jaw assembly 340, shown in FIGS. 5 and 4 respectively. However, the skilled person will understand that in other examples (not shown) the cell stand 300 of the cell testing fixture 800 may instead comprise an electrochemical cell electrical connection socket 600, for example as shown in FIG. 6.

In some examples, the electrochemical cell thermal testing fixture system 800 includes a housing (not shown) which encloses the cell stand 300 and at least a portion of the temperature-controlled plate 900. An example housing 110 is shown in FIGS. 1A and 1B.

FIG. 9A shows a schematic of a temperature control system associated with a temperature-controlled plate 900, for example the temperature-controlled plate 900 for use in the example electrochemical cell thermal testing fixtures of FIGS. 1A and 1B, 3C, and 8. Similarly, FIG. 9B shows a cross-section of an example temperature control system associated with a temperature-controlled plate, for example as schematically illustrated in FIG. 9A, in situ in an example battery thermal testing system comprising a series of electrochemical cell thermal testing fixtures, for example the battery thermal testing system of FIGS. 1A and 1B.

The temperature-controlled plate 900 comprises a first surface 900A and an opposite second surface 900B. The second surface 900B of the temperature-controlled plate 900 is in thermal contact with a first surface 910A of a thermoelectric element 910. In this example, the thermoelectric element 910 is a Peltier element. The second surface 910B of the thermoelectric element 910 is in thermal contact with a heat sink 930. Both the temperature-controlled plate 900 and the heat sink 930 are made of thermally conductive materials, for example metals, such as but not limited to, aluminium.

The heat sink 930 comprises a set of parallel fins 932 which protrude into a coolant system 940. In this example, the coolant system 940 is a fluid coolant system. The fins 932 of the heat sink 930 are arranged parallel to the direction of flow of fluid in the coolant system channel 940. In some examples, the fins 932 may have a tapered elliptical profile, for example to increase surface area for heat exchange and improve fluid dynamics when submerged in coolant fluid.

The first surface 900A of the temperature-controlled plate 900 comprises a flange 902. A PCB 920 is arranged such that least a portion of the PCB 920 is beneath the flange 902 of the temperature-controlled plate 900. The PCB 920 comprises at least one temperature sensor 925, wherein the temperature sensor 925 is arranged beneath the flange 902 of the temperature-controlled plate 900. The example shown in FIG. 9A shows only one temperature sensor 925, however the skilled person will understand a plurality of temperature sensors may be used. The PCB 920 may also comprise a local processor.

In this example, the temperature sensor 925 is mechanically biased to contact the temperature-controlled plate 900 by a resilient cut-out portion of the PCB 920. However, the skilled person will understand that the temperature sensor 925 may be mechanically biased to contact the temperature-controlled plate 900 by other mechanical biasing means.

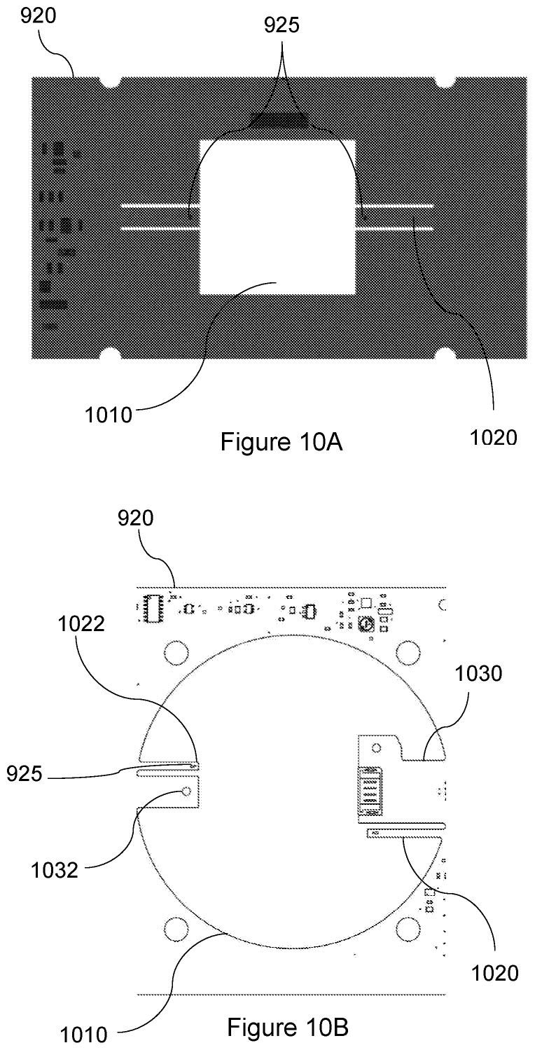

Example resilient cut-out designs for the PCB 920 are shown in more detail in FIGS. 10A and 10B.

FIGS. 10A and 10B show example PCBs 920 for use within the temperature control system associated with a temperature-controlled plate 900, for example as shown in FIGS. 9A and 9B.

The PCB 920 of FIG. 10A comprises a central square aperture 1010, wherein the aperture is sized to receive the second face 900B of the temperature-controlled plate 900. On two opposite sides of the square aperture 1010, the PCB 920 further comprises a resilient cut-out portion 1020. The resilient cut out portion 1020 has a rectangular shape, akin to a diving board. A temperature sensor 925 is arranged at the end of each cut out portion 1020 nearest to the square aperture 1010. The “diving board” cut-out portion 1020 creates a resilient force that forces the end of the cut-out portion 1020 nearest to the square aperture 1010 upwards.

Similarly, the PCB 920 of FIG. 10B comprises a central aperture 1010, wherein the aperture is sized to receive the second face 900B of the temperature-controlled plate 900. On opposite sides of the aperture 1010, the PCB 920 further comprises a resilient cut-out portion 1020 which protrudes into the aperture 1010. The resilient cut out portion 1020 has a rectangular shape, akin to a diving board. A temperature sensor 925 is arranged at the distal end 1022 of each cut out portion 1020, wherein the distal end 1022 protrudes into the aperture 1010. The “diving board” cut-out portion 1020 creates a resilient force that forces the distal end 1022 of the cut-out portion 1020 upwards. The PCB 920 of FIG. 10B additionally comprises cut-out portions 1030 which protrude into the aperture 1010. Each additional cut-out portion 1030 comprises at least one attachment aperture 1032, wherein the attachment aperture 1032 is configured to attach the PCB 920 to a temperature-controlled plate 900, for example by receiving a screw or bolt. In use, as seen in FIG. 9A, the PCB 920 of FIG. 10A or 10B is arranged such that at least the resilient cut out portion 1020 of the PCB 920 is beneath the flange 902 of the temperature-controlled plate 900. The cut-out portion 1020 then exerts a mechanical force onto the temperature sensors 925, biasing the sensors 925 to contact the flange 902 of the temperature-controlled plate 900. This may be advantageous to ensure good thermal contact between the temperature sensor 925 and the plate 900, facilitating accurate temperature measurement of the plate 900.

Returning to FIGS. 9A and 9B, the first surface 900A is configured to contact an electrochemical cell, for example the circular face of an electrochemical cell 200 as shown in FIG. 3C and FIG. 8.

The temperature sensor 925 is configured to sense the temperature of the temperature-controlled plate 900. The PCB 920 local processor is configured to adjust the temperature of the temperature-controlled plate 900 in response to an indication of the temperature sensed by the temperature sensor 925.

In use, the temperature of the temperature-controlled plate 900 is controlled using the local processor on the PCB 920. The processor receives an indication of the temperature of the temperature-controlled plate 900 from the temperature sensor 925 and, in response, adjusts the power supplied to the thermoelectric module 910 (e.g., a Peltier element) which in turn adjusts the temperature of the temperature-controlled plate 900. Excess heat is removed from the thermoelectric module 910 into the heat sink 930 by conduction. The heat sink 930 is then cooled as the fluid in the fluid coolant system 940 passes the heat sink fins 932.

In use, the temperature of the temperature-controlled plate 900 can vary between −20° C. to 75° C., however the skilled person will understand different temperature ranges may also be used. In this example, the fluid in the coolant system 940 is maintained at 20° C., however the skilled person will understand different temperatures, including temperature ranges, may also be used.

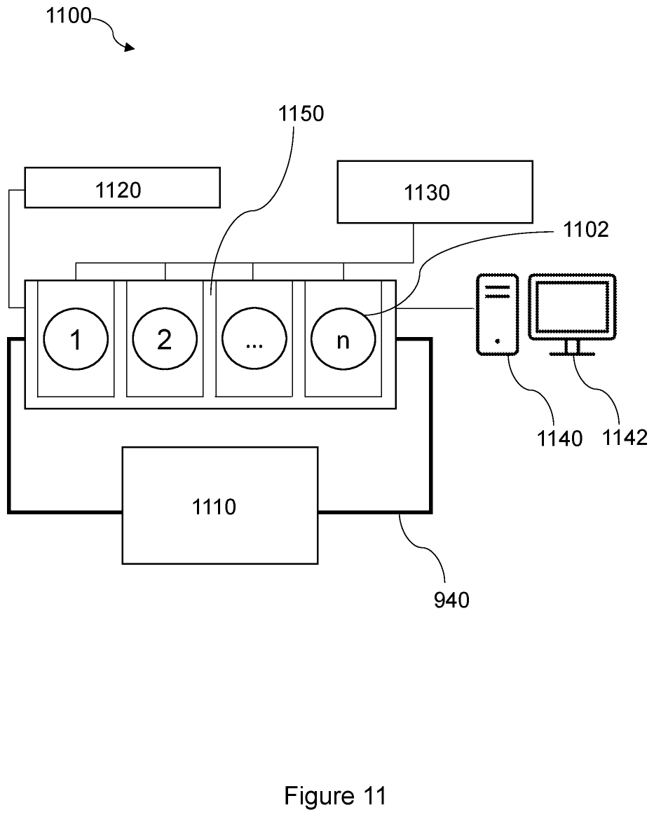

FIG. 11 shows an example battery thermal testing fixture system 1100, for example as shown in FIGS. 1A and 1B, comprising a plurality of electrochemical cell thermal testing fixtures 1102, for example but not limited to the electrochemical cell thermal testing fixtures shown in FIGS. 1A and 1B, 3C, and 8. In this example, the battery thermal testing fixture system 1100 comprises four electrochemical cell thermal testing fixtures 1102, however the skilled person will understand that any number of thermal testing fixtures 1102 may be used. The battery thermal testing system 1100 further comprises a coolant system 940, wherein the coolant system 940 is coupled to each of the plurality of electrochemical cell testing fixtures 1102. In this example, the coolant system 940 comprises a fluid cooling system and further comprises a water chiller 1110.

Each of the plurality of electrochemical cell testing fixtures 1102 are coupled together, wherein the coupling 1150 is a poor thermal conductor and/or thermally insulating. This may be advantageous to thermally decouple the plurality of electrochemical cell testing fixtures 1102 such that the temperature of each electrochemical cell testing fixtures 1102 may be independently adjusted and maintained. In this example, the coupling 1150 is a polymer, however the skilled person will understand other poor thermally conducting materials may be used.

The battery thermal testing fixture system 1100 also comprises a battery cycler 1130 coupled to each cell testing fixture 1102. The battery thermal testing fixture system 1100 additionally comprises a power supply 1120 coupled to each of the plurality of cell testing fixtures 1102.

In this example, the battery thermal testing system 1100 further comprises a control PC 1140 and display 1142. The display 1142 comprises a graphical user interface (GUI).

Each electrochemical cell testing fixture 1102 is configured to receive an electrochemical cell. In some examples, each cell testing fixture is configured to heat and/or cool the cell by conduction, for example, but not limited to, using a temperature-controlled plate and associated temperature control system configured to contact at least one surface of the cell, as shown in FIGS. 9A and 9B.

The power supply 1120 is configured to power each of the plurality of cell testing fixtures 1102. The battery thermal testing fixture system 1100 may also comprise a battery cycler 1130 configured to cycle the cells of each cell testing fixture 1102.

The display 1142 may be configured to display the test parameters and data received from each electrochemical cell testing fixture 1102 relating to corresponding electrochemical cell tests. Additionally, the GUI may be configured to receive user input to control the test parameters for each electrochemical cell testing fixture 1102, for example the GUI may be configured to receive a desired temperature input for each electrochemical cell testing fixture 1102. In response to the user input, the control PC 1140 may be configured to communicate a temperature input to the corresponding electrochemical cell testing fixture 1102. Each electrochemical cell testing fixture 1102 may locally and independently control its temperature in response to a received temperature input, for example as described in relation to FIGS. 9A and 9B.

It will be appreciated from the discussion above that the embodiments shown in the Figures are merely exemplary, and include features which may be generalised, removed, or replaced as described herein and as set out in the claims.

In the context of the present disclosure other examples and variations of the apparatus and methods described herein will be apparent to a person of skill in the art.

1. An electrochemical cell thermal testing fixture for connection to a battery cycler comprising:
a temperature-controlled plate configured to contact at least a surface of a cylindrical battery cell, wherein the temperature-controlled plate is configured to heat and/or cool the cell by conduction;
a cell stand configured to receive the one cell, wherein the cell stand comprises:
a positive contact, configured to contact a positive terminal of the cell; and
a negative contact, configured to contact a sidewall of the cell.

2. The electrochemical cell thermal testing fixture of any preceding claim further comprising means configured to mechanically bias the cell to contact the temperature-controlled plate.

3. The electrochemical cell thermal testing fixture of claim 2 wherein the mechanical biasing means configured to mechanically bias the cell to contact the temperature-controlled plate comprises the positive contact such that the mechanical biasing means is further configured to mechanically bias the positive contact to contact the cell.

4. The electrochemical cell testing apparatus of any preceding claim wherein the negative contact is mechanically biased to engage with the sidewall surface of the cylindrical cell.

5. The electrochemical cell thermal testing fixture of any preceding claim further comprising a processor and at least one temperature sensor configured to sense the temperature of the temperature-controlled plate, wherein the processor is configured to adjust the temperature of the temperature-controlled plate in response to an indication of the temperature sensed by the temperature sensor.

6. The electrochemical cell thermal testing fixture of claim 5 wherein the at least one temperature sensor configured to sense the temperature of the temperature-controlled plate is arranged on a PCB, and wherein the temperature sensor is mechanically biased to contact the temperature-controlled plate by a resilient cut-out portion of the PCB.

7. The electrochemical cell thermal testing fixture of any preceding claim further comprising at least one temperature sensor configured to sense the temperature of the cell.

8. The electrochemical cell thermal testing fixture of claim 7 wherein the temperature sensor configured to sense the temperature of the cell comprises the cell temperature testing device of claims 23 to 25.

9. The electrochemical cell thermal testing fixture of any preceding claim wherein the temperature-controlled plate is configured to contact at least a portion of a circular plane surface of the cylindrical cell.

10. The electrochemical cell thermal testing fixture of any preceding claim wherein the temperature-controlled plate further comprises a receiving portion configured to receive and contact at least a portion of the sidewall surface of the cylindrical cell.

11. An electrochemical cell electrical connection apparatus for testing cylindrical battery cells, comprising:
a positive contact, configured to contact a positive terminal of a cylindrical cell for connection to a battery cycler; and
a negative contact, configured to contact a negative sidewall surface of the cylindrical cell for connection to a battery cycler.

12. The electrochemical cell testing apparatus of claim 11 wherein the negative contact comprises a jaw assembly comprising at least a first jaw and a second jaw, wherein the first jaw and the second jaw are configured to contact opposite sides of the cell sidewall surface.

13. The electrochemical cell testing apparatus of claim 12 wherein the first jaw is configured to provide a current carrying path and the second jaw is configured to provide the voltage sense for connection to a battery cycler.

14. The electrochemical cell testing apparatus of claims 12 to 13 wherein the negative contact jaw assembly comprises a third jaw vertically displaced from the first jaw, wherein the jaws are arranged such that the second jaw is vertically displaced in between the first jaw and third jaw, and wherein the third jaw is configured to provide a current carrying path for connection to a battery cycler together with the first jaw.

15. The electrochemical cell testing apparatus of claims 12 to 14 wherein the jaw assembly is configured for a first configuration wherein the jaws are configured to contact the sidewall surface of the cylindrical cell, and a second configuration wherein the jaws are displaced such that the cell may be inserted between the jaws.

16. The electrochemical cell testing apparatus of claims 12 to 15 wherein the negative contact comprises a closing mechanism configured to reversibly operate the jaw assembly between the first and second configuration.

17. The electrochemical cell testing apparatus of claim 16 wherein the closing mechanism comprises at least one spring configured to mechanically bias the jaws to engage with the sidewall surface of the cylindrical cell.

18. The electrochemical cell thermal testing fixture of claims 1 to 10 wherein the cell stand comprises the electrochemical cell electrical connection apparatus of claims 11 to 17.

19. An electrochemical cell electrical connection socket for testing cylindrical battery cells, comprising:
a housing configured to reversibly attach to a positive circular plane surface of a cylindrical cell and at least a portion of the sidewall of the cylindrical cell, wherein the housing is made of an insulating material and further comprises:
a positive contact configured to contact the positive circular plane surface of a cylindrical cell for connection to a battery cycler; and
a negative contact configured to contact at least one of (i) the sidewall surface of the cylindrical cell, and (ii) a shoulder portion of the cylindrical cell for connection to a battery cycler.

20. The electrochemical cell electrical connection socket of claim 19 wherein the negative contact comprises a contact configured to at least partially circumferentially enclose at least a portion of the sidewall of the cylindrical cell.

21. The electrochemical cell electrical connection socket of claim 20 wherein the negative contact comprises a spring, wherein the length of the spring is configured to enclose the circumference of the cylindrical cell.

22. The electrochemical cell thermal testing fixture of claims 1 to 10 wherein the cell stand comprises the electrochemical cell electrical connection socket of claims 19 to 21.

23. An electrochemical cell temperature testing device for testing cylindrical battery cells, comprising:
a clip configured to reversibly attach to at least a portion of a cylindrical cell; and
a PCB comprising at least two temperature sensors, wherein the temperature sensors are arranged on the PCB such that the temperature sensors are configured to be arranged along the length of the clip; and
wherein the clip is configured to mechanically bias the temperature sensors to contact the cell.

24. The electrochemical cell temperature testing device of claim 23 wherein:
the temperature sensors are arranged on the PCB such that the temperature sensors are configured to be arranged along the length of the sidewall of a cylindrical cell; and
wherein the housing is configured to mechanically bias the temperature sensors to contact the sidewall of the cell.

25. The electrochemical cell temperature testing device of claims 23 to 24 wherein the device is configured to measure the temperature gradient along the length of the clip, based on the displaced temperature sensors.

26. An electrochemical cell thermal testing fixture system comprising:
a cell temperature testing device of claims 23 to 25 configured to attach to a cylindrical cell; and
a cell testing fixture of claims 1 to 10 configured to receive the cell temperature testing device and a cell.

27. The electrochemical cell thermal testing fixture system of claim 26 wherein the cell stand of the cell testing fixture of claims 1 to 10 comprises the electrochemical cell electrical connection apparatus of claims 11 to 18 or the electrochemical cell electrical connection socket of claims 19 to 22.

28. A battery thermal testing system comprising:
a plurality of electrochemical cell testing fixtures, each electrochemical cell testing fixture configured to receive a cell, wherein each cell testing fixture comprises a temperature-controlled plate configured to contact at least one surface of the cell, wherein the temperature-controlled plate is configured to heat and/or cool the cell by conduction; and
a coolant system, wherein the coolant system is configured to cool each of the plurality of electrochemical cell testing fixtures by cooling each temperature-controlled plate.

29. The battery thermal testing system of claim 28 wherein the plurality of temperature-controlled plates are coupled together, and wherein the coupling is thermally insulating.

30. The battery thermal testing system of claims 28 to 29 wherein each of the electrochemical cell testing fixtures is a cell testing fixture of claims 1 to 10 or the electrochemical cell testing fixture system of claims 26 to 27.

31. The battery thermal testing fixture system of claims 28 to 30 further comprising at least one of (i) a power supply configured to power each of the plurality of cell testing fixtures; (ii) a processor configured to control the temperature of each of the plurality of cell testing fixtures individually by adjusting the temperature of each temperature-controlled plate; and (ii) a battery cycler configured to cycle the cells of each cell testing fixture.

32. An electrochemical cell thermal testing fixture for connection to a battery cycler comprising:
a temperature-controlled plate configured to contact at least a surface of a pouch battery cell, wherein the temperature-controlled plate is configured to heat and/or cool the cell by conduction;
a cell stand configured to receive the one cell, wherein the cell stand comprises:
a positive contact, configured to contact a positive terminal of the cell; and
a negative contact, configured to contact a negative terminal of the cell.
